(19) United States
(12) Patent Application Publication
(10) Pub. No.: US 2020/0187353 A1
(43) Pub. Date: Jun. 11, 2020

(54) Printed Circuit Board And A Method For Producing Such A Printed Circuit Board

(71) Applicant: CONTINENTAL AUTOMOTIVE GmbH, Hannover (DE)

(72) Inventors: Erich MATTMANN, Heidesheim (DE); Waldemar BRINKIS, Nidderau (DE); Jürgen ZACHERL, Donaustauf (DE)

(21) Appl. No.: 16/322,022

(22) PCT Filed: Jul. 4, 2017
(86) PCT No.: PCT/EP2017/066691

§ 371 Date: Jan. 30, 2019

(30) Foreign Application Priority Data
Aug. 2, 2016 (DE) 10 2016 214 265.8

(51) Int. Cl. H05K 1/11; H05K 1/03; H05K 3/00; H05K 3/34

(52) U.S. Cl. CPC H05K 1/116; H05K 1/0306; H05K 2201/10151; H05K 3/3484; H05K 3/0094

(57) ABSTRACT

A printed circuit board, preferably for use in a fuel fill-level sensor and in a fuel fill-level measuring system, having conductor tracks formed on two sides of a ceramic substrate. The ceramic substrate has at least one metalized hole for through-contacting that connects the conductor tracks to one another. The hole of the sintered ceramic substrate is filled with a metal-containing sintering paste, which is introduced under pressure. In the fully sintered state, the paste enters into at least one integral bond with the ceramic substrate and completely fills the hole in so doing.

### CROSS REFERENCE TO RELATED APPLICATIONS

This is a U.S. national stage of application No. PCT/EP2017/066691, filed on Jul. 4, 2017. Priority is claimed on German Application No. DE102016214265.8, filed Aug. 2, 2016, the content of which is incorporated herein by reference.

### BACKGROUND OF THE INVENTION

### 1. Field of the Invention

The present invention relates to a printed circuit board, a sensor having such a printed circuit board, a fuel fill-level measuring system for a vehicle having such a sensor, and a method for producing such a printed circuit board.

### 2. Description of the Prior Art

According to the prior art, printed circuit boards functioning as circuit carriers on two sides are known. Such printed circuit boards can have, for example, a sintered ceramic as carrier material for conductor tracks. Furthermore, such printed circuit boards can have metalized holes that interconnect the conductor tracks, which are formed on two sides of the circuit carrier.

Such a printed circuit board can be found, for example, in a so-called magnetic passive position sensor, also termed MAPPS, which is used in a fuel tank of a motor vehicle for fuel fill-level detection. Such a sensor contains a printed circuit board having a circuit carrier or substrate consisting of a sintered ceramic, which is provided on one side with conductor tracks and with a contact spring structure, wherein the contact spring structure interacts with the conductor tracks. Depending on the fuel fill-level of the tank, this contact spring structure is contacted with the conductor tracks by a magnet. Here, the sintered ceramic comprises, for example, two metalized holes to interconnect the conductor tracks on both sides of the sintered ceramic.

To metalize these holes, a layer of an electrically conducting thick-layer paste or sintering paste is first deposited on one side of the sintered ceramic substrate in the region of the holes. This paste is then partly drawn into the holes from the other side by a negative pressure. The ceramic substrate is then dried and fired, with the result that the thick-layer paste or sintering paste fully sinters and enters into an integral bond with the ceramic substrate.

An analogous procedure is then carried out with respect to the other side of the ceramic substrate. As a result, a first layer and a second layer of a respectively electrically conducting thick-layer paste thus partly overlap in the holes, thereby creating a through-contacting.

The holes are finally closed by a glass compound so that the side of the substrate that is equipped with the conductor tracks and the contact spring structure can be encapsulated in a liquid-tight or hermetic manner.

### SUMMARY OF THE INVENTION

It is an object of one aspect of the present invention to improve such a through-contacting.

Aspects of the invention include a printed circuit board, a sensor having such a printed circuit board, a fuel fill-level measuring system having such a sensor, and a method for producing the proposed printed circuit board. A printed circuit board having conductor tracks formed on two sides of a ceramic substrate, wherein the ceramic substrate has at least one metalized hole for through-contacting, which hole connects the conductor tracks to one another.

The hole of the sintered ceramic substrate is filled with a metal-containing sintering paste which is introduced under pressure, which sintering paste in the fully sintered state, enters into at least one integral bond with the ceramic substrate and completely fills the hole in so doing.

Depending on whether, during the filling of the hole with the sintering paste, an overhang of material or a material plug forms which engages behind the respective ceramic substrate side or the respective hole edge, a form fit can also occur between the ceramic substrate and the sintering paste. Such a plug can represent a material overhang of sintering paste with respect to the respective substrate side of about 2 to 5 μm.

A printed circuit board or board or circuit board within the context of this application is to be understood as meaning a printed circuit board whose carrier material or substrate is suitable for a high-temperature or sintering process, that is to say for a treatment at about 950° C. or else at about 1500° C. A carrier material or substrate consisting of an aluminum oxide ceramic is suitable for treatment at such high temperatures.

The conductor tracks can be applied to or deposited on the carrier material or substrate by printing using the screen printing method or stencil printing method. A ceramic substrate carrier printed in such a way is fired, wherein the conductor tracks fuse or fully sinter to form very resistant and reliable layers. In principle, such a firing operation can take place using so-called low-temperature cofired ceramics (LTCC) or high-temperature cofired ceramics (HTCC) technology.

Here, sintering or full sintering is to be understood as meaning a solidification and compaction of a sintering paste to form a compact material as a result of a temperature treatment in a sintering furnace.

The ceramic substrate carrier to be through-contacted according to one aspect of this invention is already fully sintered before its at least one hole is filled with the sintering paste.

The filling operation according to the invention can be fundamentally distinguished from the filling of VIAs or VIA filling known from the prior art (VIA hole filling; VIA=vertical interconnect access). The filling of VIAs or VIA filling is to be understood as meaning a filling of a hole of a green body—also termed “green tape” or sintering film—in screen printing or stencil printing for the purpose of a through-contacting.

Such a green body (“green tape”) here consists of a layer of a dry, but unsintered sintering compound or film, for instance consisting of aluminum oxide ceramic, which is compacted and solidified to form a solid carrier material during a drying and during a firing operation in a sintering furnace. During the production, this green body layer is applied to a plastic carrier film and wound up into a roll.

Such a green body layer or sintering paste layer can have a thickness of about 0.1 mm in the dried, but unsintered state. A plurality of such layers of sintering pastes consisting of aluminum oxide ceramic can be stacked on one another depending on the application. Here, each layer of such a stack of layers can have conductor tracks, resistors and at least one hole for the through-contacting of the layer. Here, such holes are filled with a thick layer (VIA filling) in screen printing or stencil printing. In other words, these holes are already filled before the stack is pressed together. Such a stack is then isostatically compressed, but not for example to fill or completely fill the holes, but rather to compress the stack. Such a compressed stack of individual green body layers is finally fully sintered in a furnace or formed into a solid or compacted and solidified sintered ceramic as a result of the drying and the firing operation in the furnace.

Sintering in connection with the through-contacting is understood in the context of this application as meaning an operation in which a physically solid and electrically conducting structure results from a pasty mixture—for instance consisting of a noble metal, a glass, a resin and a thinning agent—for use as a conducting paste or sintering paste.

Such a metalization of the hole ensures a failsafe through-contacting of the substrate because sufficient electrically conducting material is present at each point of the hole.

Moreover, such a metalization requires a smaller region around the hole, which region has to be metalized for the purpose of the through-contacting.

According to one embodiment, the metal-containing sintering paste is a silver- and palladium-containing paste or silver-palladium paste.

Here, the silver-palladium paste has a palladium content of at least 5%, preferably 10 to 15%. Here, the palladium is an important constituent part of the paste composition since it increases the adhesive strength of the sintering paste in the hole of the sintered ceramic substrate. Such a hole is drilled of a laser. Here, vitrification occurs on the surface of the hole and makes bonding with the sintering paste more difficult. The addition of palladium substantially improves the bonding mechanism upon pressing the sintering paste into the hole.

The palladium content in the sintering paste additionally brings about a better compatibility with a metallic sintering paste functioning as a conductor track, which sintering paste is subsequently printed on by screen printing or stencil printing in the region of the completely filled hole, in that the palladium reduces or eliminates the so-called Kirkendall effect, which is known as such to a person skilled in the art.

The Kirkendall effect consists in the fact that, given a sufficiently high temperature with two solid phases lying on one another, the volume of the one phase decreases, whereas the volume of the other phase increases. The effect is particularly noticeable if the phase boundary has been previously marked since a displacement of the marking relative to an outer sample geometry is then observed. The phase boundary does not migrate itself, but matter between the phases and hence the position of the phase boundary relative to the outer sample geometry moves. Here, the metal-containing sintering paste can be lead-containing or lead-free depending on what requirements are placed on the sintering paste.

According to one embodiment, the ceramic substrate has at least two such metalized holes for through-contacting, which holes connect the conductor tracks to one another, wherein the holes can be formed with equal and/or different diameters.

Also proposed is a sensor, in particular a fuel fill-level sensor, having a printed circuit board of the above-described type. According to one embodiment, such a printed circuit board is proposed in particular for use in a so-called magnetic passive position sensor, also termed MAPPS. Such a sensor is described, for example, in patent EP 0 844 459 B1, which is incorporated by reference and is hereby made part of the disclosure of this description.

In addition, a fuel fill-level measuring system for a motor vehicle having a sensor of the above-described type is proposed.

Moreover, a method for producing a printed circuit board of the above-described type is proposed in which at least one hole of a sintered ceramic substrate of the printed circuit board is metalized in order to obtain a through-contacting of the ceramic substrate. The ceramic substrate can be an aluminum oxide ceramic.

Here, the hole of the ceramic substrate is filled with a metal-containing sintering paste under application of a pressure, wherein the sintering paste is then dried and fired and in so doing fully sinters upon firing. The sintering here takes place under the action of temperature at about 850° C., for example in a furnace and/or by means of other heat sources.

Here, in the fully sintered state, the sintering paste enters into at least one integral bond with the ceramic substrate and completely fills the hole in so doing.

Depending on whether, during the filling of the hole with the sintering paste, an overhang of material or a material plug is formed which engages behind the respective ceramic substrate side or the respective hole edge, a form fit can also occur between the ceramic substrate and the sintering paste. Such a plug can represent a material overhang of sintering paste with respect to the respective substrate side of about 2 to 5 μm.

According to one embodiment, a pressure of preferably 2 to 4 bar is applied by a movable component in order to compress the sintering paste. A movable component within the context of this application is to be understood as meaning a plunger which, with a surrounding housing, forms a closed-off space filled with the sintering paste to be compressed. Here, the plunger can have an elongate extent, for instance in the form of a sword, in order to be able to simultaneously fill a plurality of holes which are arranged in a row relative to one another. According to one embodiment, the pressure is 3 bar.

Such a pressure must be applied for substrate thicknesses starting from about 0.25 mm in order to ensure a filling of the hole of the sintered ceramic substrate. In principle, the aforementioned pressure range is suitable for processing substrate thicknesses of about 0.25 mm to 5 mm. According to one embodiment, the preferred range of substrate thicknesses is 0.5 mm to 0.7 mm.

According to a further embodiment, it is advantageously possible for at least two such holes having equal and/or different diameters to be filled or completely filled simultaneously with the sintering paste in order to ensure optimization of the method. A plurality of such ceramic substrates having holes which are metalized in such a way can thus be simultaneously produced in terms of the method.

Here, the ceramic substrate can be fixed on a carrier by a negative pressure in that the ceramic substrate is drawn against the carrier via at least one suction channel formed in the carrier after the substrate has previously been correspondingly oriented or has been positioned with the aid of at least one stop.

The at least one hole of the ceramic substrate is expediently completely filled using a template. Impurities on one side of the substrate can thereby be avoided. In order also to protect the other side of the ceramic substrate from impurities, a flexible layer can be used that is arranged between the ceramic substrate and the carrier. According to one embodiment, a paper layer is used for this purpose. Here, the ceramic substrate can be bordered by a reinforcing frame that protects the substrate from damage as a result of being subjected to pressure when completely filling the holes with the sintering paste.

Finally, conductor tracks of different widths and thickness can be deposited by screen printing or stencil printing on a substrate, which is through-contacted in such a way.

### BRIEF DESCRIPTION OF THE DRAWINGS

The invention will be explained in detail in the following text with reference to the illustrations in the figures. Further advantageous developments of the invention can be gathered from the dependent claims and the following description of preferred embodiments. In the drawings:

FIG. 1 is a schematic illustration of a metalization of a substrate hole according to the prior art;

FIG. 2 is a schematic illustration of a metalization according to the invention of a substrate hole; and

FIG. 3 is a schematic illustration of a pressure-filling device.

### DETAILED DESCRIPTION OF THE PRESENTLY PREFERRED EMBODIMENTS

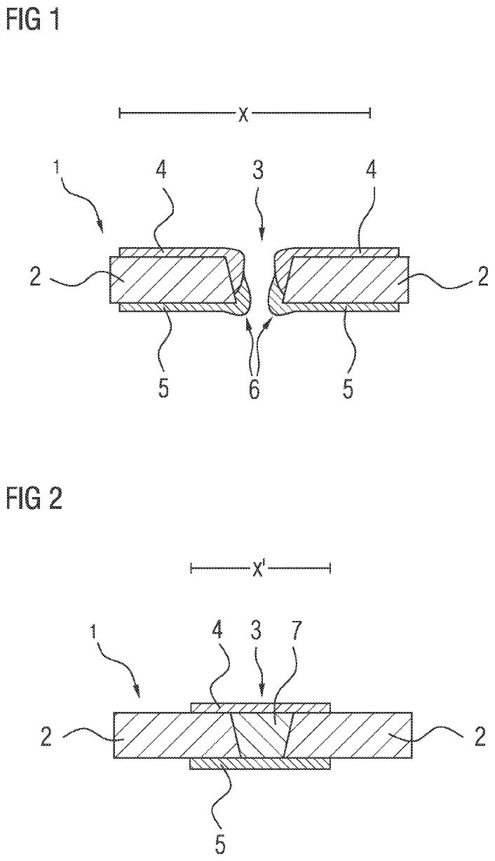

FIG. 1 illustrates a substrate 2 as part of a printed circuit board 1. Here, the substrate 2, which can be produced from a sintered ceramic, for example an aluminum oxide ceramic, has a hole 3 and is printed on a first side with a first electrically conducting layer 4 or a thick layer 4 and on a second side, which is opposite to the first side, with a second electrically conducting layer 5 or thick layer 5. Here, the hole 3 is of conical design for production-related reasons. The two thick layers 4, 5 extend partly into the hole 3 and overlap in so doing. Such a coating of the hole 3 constitutes a through-contacting of the substrate 2, by which through-contacting conductor tracks 4, 5 formed on the two sides of the substrate 2 are connected to one another.

Such a coating of the hole 3 is achieved by the fact that the two thick layers 4, 5 are successively partly drawn into the hole 3 from the respective opposite side of the substrate 2 by a negative pressure. In this example, the thick layer 4 has been drawn in first of all and then fully sintered in a furnace. The thick layer 5 has subsequently been drawn in and fully sintered in the furnace.

Here, there can occur a formation of weak points with very small layer thicknesses, for instance a weak point 6 at the lower one of the two hole edges. Such a weak point 6, which can have a layer thickness of about 1 to 2 μm, can even lead to a failure of the through-contacting under a high current load. If the hole 3 is furthermore closed, for instance by a further printed layer or by further printed layers, or in that, for example, a glass compound is incorporated or introduced into the hole 3, because for instance one of the two substrate sides is intended to be hermetically closed off, such a filling of the hole 3 can thus lead to an excessive change in the resistance and therefore also to an excessive change in the electrical behavior of the through-contacting, wherein this change as such can be unacceptable.

FIG. 2 illustrates a proposed improvement whereby the hole 3 in the substrate 2 is completely filled with a metal-containing sintering paste 7 or conducting paste, preferably a silver-palladium paste. Here, the sintering paste 7 is at least integrally bonded with the substrate 2. In addition to this, the sintering paste 7 can also be connected to the substrate 2 in a form-fitting manner, even though this is not illustrated in FIG. 2. This depends on whether, during the filling of the hole with the sintering paste, an overhang of material or a material plug is formed which engages behind the respective substrate side or the respective hole edge. In addition, the substrate 2 is printed in the region of the completely filled hole 3 on both sides with in each case an electrically conducting thick layer 4, 5.

Here, the sintering paste 7, which completely fills the hole 3, is a pasty mixture that at least comprises silver, palladium, a glass, a resin, and a thinning agent. Upon running through a sintering furnace, this sintering paste 7 is solidified and compacted to form a physically solid and electrically conducting structure. Here, the sintering paste 7 contains a palladium content of preferably 10 to 15%. Here, the sintering paste 7 can be lead-containing or lead-free depending on the application. An advantage of such a metalization of the hole 3 is that sufficient electrically conducting material is present at each point of the hole in order to ensure a failsafe through-contacting of the substrate 2.

In addition, the region X′ around the hole 3 that is required for metalization according to FIG. 2 is smaller by comparison with the region X according to FIG. 1. Therefore, the proposed type of metalization also leads to a saving of space. The region X can be about 600 to 900 μm and the region X′ can be about 300 μm and less. As a result, the region X′ is thus at most half the size of the region X.

The substrates illustrated in FIGS. 1 and 2 each have a thickness of about 0.63 mm. Furthermore, the holes 3 illustrated in FIGS. 1 and 2 each have a conical shape. Such a conical shape arises for production-related reasons when drilling the holes by a laser. Here, the upper hole diameter can be about 0.1 to 0.3 mm.

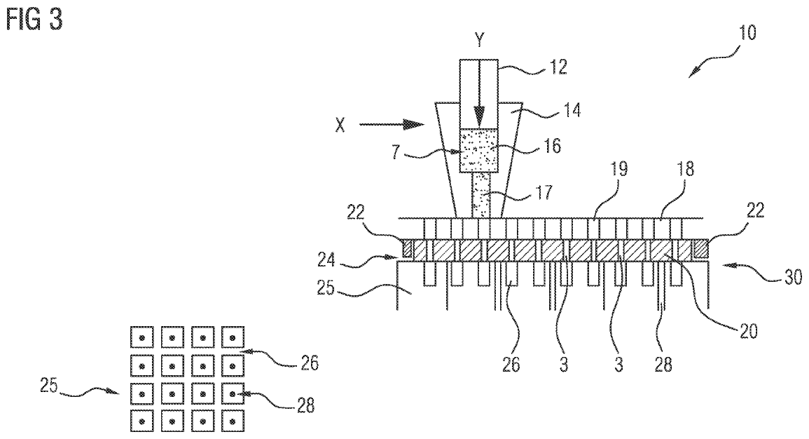

FIG. 3 illustrates an arrangement 30 of a substrate matrix 20 in a pressure-filling device 10. Such a substrate matrix 20 consequently gives rise to a plurality of substrates 2 (cf. FIG. 2). For example, the substrate matrix 20 can comprise a total of 16 substrates 2, for instance in a 2×8 arrangement, that is to say in an arrangement having two rows and in each case 8 substrates 2. Here, the pressure-filling device 10 allows at least a simultaneous filling of the holes 3, which are arranged in a row, of the substrate matrix 20 with said sintering paste 7. Here, this row of holes extends conceptually in a vertical direction with respect to FIG. 3 or with respect to the plane of the drawing.

Specifically there can be seen the substrate matrix 20, which is arranged on a carrier 25. Here, the substrate matrix 20 is preferably bordered by a reinforcing frame 22 and positioned with respect to the carrier 25 in such a way that the holes 3 of the individual substrates 2 are aligned with channels 26 of the carrier 25, which are arranged at right angles to one another. Here, the positionally accurate alignment of the substrate matrix 20 can be ensured, for example, via at least one corresponding stop (not shown) which is formed for instance on the carrier 25 and against which, for example, the reinforcing frame 22 can butt. The carrier 25 further comprises vertically extending suction channels 28 via which the substrate matrix 20 is sucked against the carrier 25 by a negative pressure and thus fixed.

Between the substrate matrix 20 and the carrier 25 there is expediently arranged a flexible layer 24, preferably in the form of a paper layer, which catches the sintering paste 7.

Lying expediently on the substrate matrix 20 is a template 18 having a plurality of holes 19 which are aligned with the holes 3 which need to be filled. The thickness of the template is about 0.1 mm. Indicated above the template 18 is a doctor blade 14 by which said row of holes in the substrate matrix 20 is completely filled with the sintering paste 7. Here, this doctor blade 14 encompasses a collecting chamber 16 and an adjoining, smaller chamber 17 which can cover the row of holes in the substrate matrix 20.

Here, the filling of the substrate matrix 20 proceeds as follows: By means of a plunger of elongate design in the form of a sword 12, which is movable in the collecting chamber 16, the sintering paste 7 situated in the chamber 16 is pressed in the vertical direction Y into the holes 3 of the row of holes via the chamber 17 and the template 18. Here, a pressure of about 2 to 4 bar is applied. In this example, a pressure of about 3 bar is applied. Here, the sintering paste 7 is introduced into the holes 3 in a metered manner in such a way that there are formed on the underside of the substrate matrix 20 only very small overhangs of material or material plugs that extend into the channel 26 and in so doing locally arch the paper layer 24 without tearing or damaging it. The individual plugs here form a material overhang with respect to the underside of the substrate matrix 20 of about 2 to 5 μm.

The doctor blade 14 moves from row of holes to row of holes in the horizontal direction X in order to successively fill the individual rows of holes with the sintering paste 7. Both the template 18, over which the doctor blade 14 sweeps, and the paper layer 24 serve to prevent smearing of the substrate matrix 20.

In principle, there is also formed a slight material overhang with respect to the upper side of the substrate matrix 20, with the result that the fillings of the individual holes 3 substantially have the form of a rivet.

Subsequently to the above-described filling operation, the substrate matrix 20 runs through a sintering furnace. Here, the fillings of the individual holes 3 are solidified and compacted to form a physically solid and electrically conducting structure. In the sintering furnace, the substrate matrix 20 runs through a temperature profile with temperatures of up to 850° C. Here, the fillings of the individual holes 3 experience both a reduction and an oxidation and in so doing enter into at least one integral bond with the ceramic substrate 2. In the fully sintered state, these fillings completely fill the respective holes.

Although exemplary embodiments have been discussed in the above description, it should be noted that numerous modifications are possible. Furthermore, it should be noted that the exemplary embodiments are merely examples which are not intended to limit the scope of protection, applications and structure in any way. Rather, the above description will provide a person skilled in the art with a guideline for implementing at least one exemplary embodiment, wherein various modifications, in particular with regard to the function and arrangement of the described constituent parts, may be made without departing from the scope of protection as defined by the claims and by these equivalent combinations of features.

1.-16. (canceled)

17. A printed circuit board comprising:
a ceramic substrate;
conductor tracks which are formed on two sides of the ceramic substrate;
at least one metalized hole defined by the ceramic substrate that connects the conductor tracks to one another; and
a metal-containing sintering paste which is introduced under pressure into the at least one metalized hole of the ceramic substrate, which metal-containing sintering paste, in a fully sintered state, enters into at least one integral bond with the ceramic substrate and completely fills the at least one metalized hole.

18. The printed circuit board as claimed in claim 17, wherein the metal-containing sintering paste is a silver-palladium paste.

19. The printed circuit board as claimed in claim 18, wherein the silver-palladium paste has a palladium content of at least one of 5%, 10%, and 15%.

20. The printed circuit board as claimed in claim 17, wherein the metal-containing sintering paste is lead-containing or lead-free.

21. The printed circuit board as claimed in claim 17, wherein a thickness of the ceramic substrate is 0.5 mm to 0.7 mm.

22. The printed circuit board as claimed in claim 17, wherein the ceramic substrate has at least two metalized holes for through-contacting, which holes connect the conductor tracks to one another, wherein the holes are formed with equal and/or different diameters.

23. The printed circuit board as claimed in claim 17, configured as a fuel fill-level sensor.

24. The printed circuit board as claimed in claim 17, configured as a fuel fill-level sensor for a fuel fill-level measuring system.

25. A method for producing a printed circuit board, comprising:
providing a ceramic substrate having at least one hole defined by the ceramic substrate;
forming conductor tracks on two sides of the ceramic substrate that are connected to one another by the at least one hole, the at least one hole of the ceramic substrate of the printed circuit board is metalized in order to obtain a through-contacting of the ceramic substrate;
filling the at least one hole of the ceramic substrate with a metal-containing sintering paste under application of a pressure; and
drying and firing the metal-containing sintering paste which is fully sintered upon firing,
wherein, in a fully sintered state, the metal-containing sintering paste enters into at least one integral bond with the ceramic substrate and completely fills the at least one hole.

26. The method as claimed in claim 25, wherein a pressure of 2 to 4 bar is applied by a movable component to compress the metal-containing sintering paste.

27. The method as claimed in claim 25, wherein at least two holes having equal and/or different diameters that are metalized.

28. The method as claimed in claim 25, further comprising:
fixing the ceramic substrate on a carrier by a negative pressure such that the ceramic substrate is drawn against the carrier via at least one suction channel formed in the carrier.

29. The method as claimed in claim 25, wherein the at least one hole of the ceramic substrate is completely filled using a template.

30. The method as claimed in claim 28, further comprising:
arranging a flexible layer between the ceramic substrate and the carrier.

31. The method as claimed in claim 30, wherein a paper layer is used as the flexible layer.

32. The method as claimed in claim 25, wherein a reinforcing frame is used that borders the ceramic substrate.
